(19) United States
(12) Patent Application Publication
(10) Pub. No.: US 2012/0178259 A1
(43) Pub. Date: Jul. 12, 2012

(54) METHOD OF CLEANING SILICON CARBIDE SEMICONDUCTOR AND APPARATUS FOR CLEANING SILICON CARBIDE SEMICONDUCTOR

(75) Inventors: Tomihito Miyazaki, Osaka-shi (JP); Keiji Wada, Osaka-shi (JP); Toru Hiyoshi, Osaka-shi (JP)

(73) Assignee: SUMITOMO ELECTRIC INDUSTRIES, LTD., Osaka-shi (JP)

(21) Appl. No.: 13/395,621

(22) PCT Filed: Apr. 21, 2011
(86) PCT No.: PCT/JP2011/059820

§ 371 Date: Mar. 12, 2012

(30) Foreign Application Priority Data
Jun. 16, 2010 (JP) 2010-136869

(51) Int. Cl. H01L 21/31; C23F 17/00

(52) U.S. Cl. 438/694; 118/620; 257/E21.24

(57) ABSTRACT

A method of cleaning an SiC semiconductor includes the steps of forming an oxide film on a surface of an SiC semiconductor and removing the oxide film. In the step of removing the oxide film, the oxide film is removed with halogen plasma or hydrogen plasma. In the step of removing the oxide film, fluorine plasma is preferably employed as halogen plasma. The SiC semiconductor can be cleaned such that good surface characteristics are achieved.

### TECHNICAL FIELD

The present invention relates to a method of cleaning a silicon carbide (SiC) semiconductor and an apparatus for cleaning an SiC semiconductor, and more particularly to a method of cleaning an SiC semiconductor having an oxide film and used in a semiconductor device and an apparatus for cleaning an SiC semiconductor.

### BACKGROUND ART

In a method of manufacturing a semiconductor device, cleaning has conventionally been performed to remove deposits deposited on a surface. Such a cleaning method includes a technique disclosed, for example, in Japanese Patent Laying-Open No. 6-314679 (Patent Literature 1). This Patent Literature 1 discloses a method of cleaning a semiconductor substrate as follows. Initially, a silicon (Si) substrate is cleaned with ultrapure water containing ozone to form an Si oxide film, so that particles and a metal impurity are taken into the inside or into a surface of this Si oxide film. Then, this Si substrate is cleaned with a diluted hydrofluoric acid aqueous solution to etch away the Si oxide film and to simultaneously remove the particles and the metal impurity.

### CITATION LIST

### Patent Literature

PTL 1: Japanese Patent Laying-Open No. 6-314679

### SUMMARY OF INVENTION

### Technical Problem

SiC has a large band gap and also has maximum breakdown electric field and thermal conductivity higher than those of Si, and SiC has carrier mobility as high as that of Si and it is high also in electron saturation drift velocity and breakdown voltage. Therefore, application to a semiconductor device required to achieve higher efficiency, higher breakdown voltage and larger capacity is expected. Then, the present inventor paid attention to use of an SiC semiconductor for a semiconductor device. In using an SiC semiconductor for a semiconductor device, a surface of an SiC semiconductor should be cleaned.

The present inventor, however, found that, when an Si oxide film is formed on an SiC semiconductor and the Si oxide film is cleaned with a diluted hydrofluoric acid aqueous solution in an attempt to apply the cleaning method disclosed in Patent Literature 1 above to the SiC semiconductor, an etching rate differs in a plane of the SiC semiconductor due to film quality of the Si oxide film depending on a plane orientation. If in-plane variation is caused by removal of the Si oxide film in the SiC semiconductor, a region where cleaning is insufficient, such as a residual Si oxide film, may result. Even though the Si oxide film has completely been removed, etching will develop only in a partial region in the plane of the SiC semiconductor and surface characteristics of the SiC semiconductor will vary. Therefore, good surface characteristics of the SiC semiconductor after cleaning cannot be achieved.

Therefore, an object of the present invention is to provide an SiC semiconductor cleaning method and an SiC semiconductor cleaning apparatus for cleaning an SiC semiconductor such that good surface characteristics are achieved.

### Solution to Problem

A method of cleaning an SiC semiconductor according to the present invention includes the steps of forming an oxide film on a surface of an SiC semiconductor and removing the oxide film. In the step of removing the oxide film, the oxide film is removed with the use of halogen plasma or hydrogen (H) plasma.

According to the method of cleaning the SiC semiconductor in the present invention, by forming an oxide film on the surface of the SiC semiconductor, an impurity, particles and the like deposited on the surface can be taken into the oxide film. This oxide film is removed with the use of halogen plasma or H plasma, and therefore influence by anisotropy due to plane orientation of SiC can be lessened. Thus, the oxide film formed on the surface of the SiC semiconductor can be removed to thereby lessen in-plane variation. Therefore, an impurity, particles and the like on the surface of the SiC semiconductor can be removed to lessen in-plane variation. In addition, since the SiC semiconductor is a stable compound, even use of halogen plasma is less likely to damage the SiC semiconductor. Therefore, the SiC semiconductor can be cleaned such that good surface characteristics are achieved.

In the method of cleaning an SiC semiconductor above, preferably, in the step of removing the oxide film, fluorine (F) plasma is used as the halogen plasma.

F plasma is high in etching efficiency and low in possibility of metal contamination. Therefore, the SiC semiconductor can be cleaned such that better surface characteristics are achieved.

In the method of cleaning an SiC semiconductor above, preferably, in the step of removing the oxide film, the oxide film is removed at a temperature not lower than 20° C. and not higher than 400° C.

Thus, damage to the SiC semiconductor can be lowered.

In the method of cleaning an SiC semiconductor above, preferably, in the step of removing the oxide film, the oxide film is removed at a pressure not lower than 0.1 Pa and not higher than 20 Pa.

Thus, since reactivity between halogen plasma or H plasma and the oxide film can be enhanced, the oxide film can readily be removed.

In the method of cleaning an SiC semiconductor above, preferably, oxygen (O) plasma is used in the step of forming an oxide film.

By using O plasma, the oxide film can readily be formed on the surface of the SiC semiconductor which has strong bond and represents a stable compound. Therefore, the oxide film can readily be formed with an impurity, particles and the like deposited on the surface being taken therein. By removing this oxide film with halogen plasma, the impurity, the particles and the like on the surface of the SiC semiconductor can be removed. In addition, since the SiC semiconductor is a stable compound, even use of O plasma is less likely to damage the SiC semiconductor. Therefore, the SiC semiconductor can be cleaned such that better surface characteristics are achieved.

In the method of cleaning an SiC semiconductor above, preferably, the SiC semiconductor is arranged in an atmosphere cut off from the air between the step of forming an oxide film and the step of removing the oxide film.

Thus, an impurity in the air can be prevented from redepositing onto the surface of the SiC semiconductor. Therefore, the SiC semiconductor can be cleaned such that better surface characteristics are achieved.

An apparatus for cleaning an SiC semiconductor according to one aspect of the present invention includes a forming portion, a removal portion, and a connection portion. The forming portion forms an oxide film on a surface of an SiC semiconductor. The removal portion removes the oxide film with halogen plasma or H plasma. The connection portion connects the forming portion and the removal portion to each other for allowing the SiC semiconductor to be carried therein. A region in the connection portion for carrying the SiC semiconductor can be cut off from the air.

An apparatus for cleaning an SiC semiconductor according to another aspect of the present invention includes a forming portion for forming an oxide film on a surface of an SiC semiconductor and a removal portion for removing the oxide film using halogen plasma or H plasma, and the forming portion and the removal portion are common.

According to the apparatuses for cleaning an SiC semiconductor according to one and another aspects of the present invention, while an oxide film is removed in the removal portion after the oxide film is formed on the SiC semiconductor in the forming portion, the SiC semiconductor can be prevented from being exposed to the air. Thus, an impurity in the air can be prevented from redepositing onto the surface of the SiC semiconductor. In addition, since halogen plasma or H plasma is used to remove that oxide film in which an impurity, particles and the like have been taken in, influence by anisotropy due to plane orientation of SiC can be lessened. Thus, the oxide film formed on the surface of the SiC semiconductor can be removed to lessen in-plane variation. Therefore, the SiC semiconductor can be cleaned such that good surface characteristics are achieved.

### Advantageous Effects of Invention

As described above, according to the method and the apparatus for cleaning an SiC semiconductor in the present invention, by removing the oxide film formed on the surface with the use of halogen plasma or H plasma, the SiC semiconductor can be cleaned such that good surface characteristics are achieved.

### BRIEF DESCRIPTION OF DRAWINGS

FIG. 1 is a schematic diagram of an apparatus for cleaning an SiC semiconductor in a first embodiment of the present invention.

FIG. 2 is a cross-sectional view schematically showing an SiC semiconductor prepared in the first embodiment of the present invention.

FIG. 3 is a flowchart showing a method of cleaning an SiC semiconductor in the first embodiment of the present invention.

FIG. 4 is a cross-sectional view schematically showing a state in which an oxide film is formed on the SiC semiconductor in the first embodiment of the present invention.

FIG. 5 is a cross-sectional view schematically showing a state in which the oxide film has been removed in the first embodiment of the present invention.

FIG. 6 is a schematic diagram of an apparatus for cleaning an SiC semiconductor in a variation of the first embodiment of the present invention.

FIG. 7 is a cross-sectional view schematically showing an SiC semiconductor to be cleaned in a second embodiment of the present invention.

FIG. 8 is a flowchart showing a method of cleaning an SiC semiconductor in the second embodiment of the present invention.

FIG. 9 is a cross-sectional view schematically showing one step in the method of cleaning an SiC semiconductor in the second embodiment of the present invention.

FIG. 10 is a cross-sectional view schematically showing one step in the method of cleaning an SiC semiconductor in the second embodiment of the present invention.

FIG. 11 is a cross-sectional view schematically showing one step in the method of cleaning an SiC semiconductor in the second embodiment of the present invention.

FIG. 12 is a cross-sectional view schematically showing an epitaxial wafer to be cleaned in an example.

### DESCRIPTION OF EMBODIMENTS

An embodiment of the present invention will be described hereinafter with reference to the drawings. In the drawings below, the same or corresponding elements have the same reference characters allotted and description thereof will not be repeated.

### First Embodiment

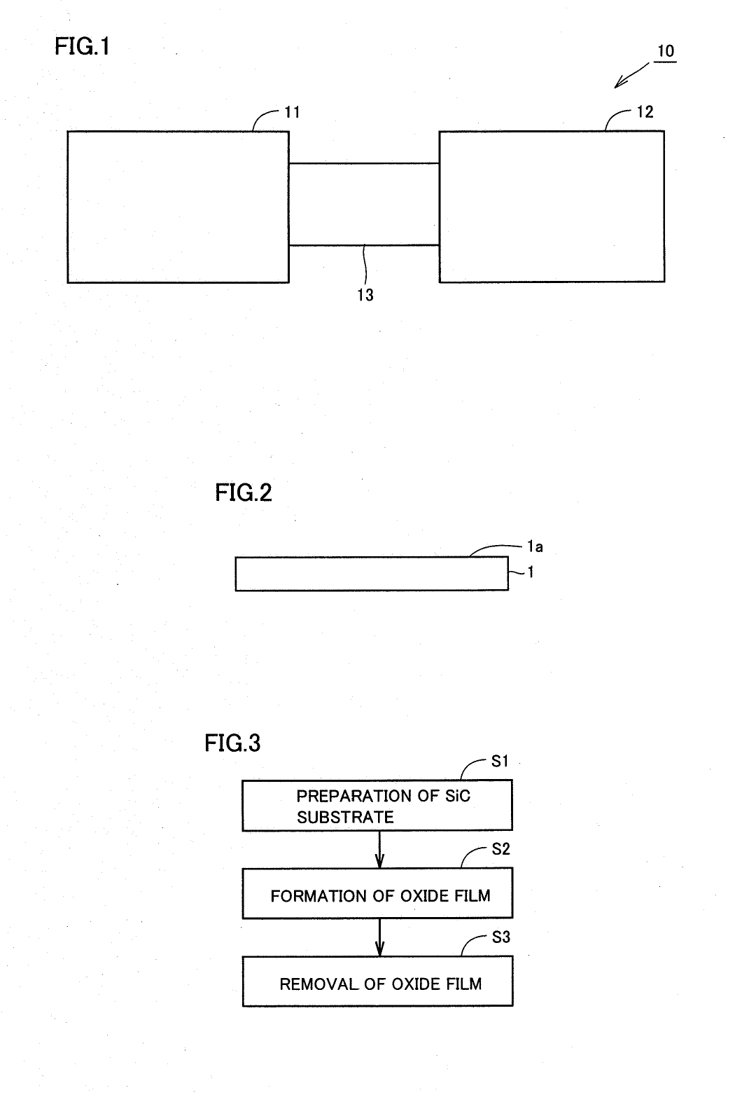

FIG. 1 is a schematic diagram of an apparatus for cleaning an SiC semiconductor in a first embodiment of the present invention. The apparatus for cleaning an SiC semiconductor in one embodiment of the present invention will be described with reference to FIG. 1.

As shown in FIG. 1, an SiC semiconductor cleaning apparatus 10 includes a forming portion 11, a removal portion 12, and a connection portion 13. Forming portion 11 and removal portion 12 are connected to each other through connection portion 13. The insides of forming portion 11, removal portion 12 and connection portion 13 are cut off from the air, and the insides can communicate with one another. Forming portion 11 forms an oxide film on the surface of an SiC semiconductor.

For example, a plasma generation apparatus, an apparatus for forming an oxide film using a solution containing O such as ozone water, and the like are employed as forming portion 11.

Removal portion 12 removes the oxide film formed in forming portion 11. The plasma generation apparatus is employed as removal portion 12. Removal portion 12 removes the oxide film with the use of halogen plasma or hydrogen plasma.

The plasma generation apparatus employed for forming portion 11 and removal portion 12 is not particularly limited, and for example, a parallel plate RIE (Reactive Ion Etching) apparatus, an ICP (Inductive Coupled Plasma) RIE apparatus, an ECR (Electron Cyclotron Resonance) RIE apparatus, an SWP (Surface Wave Plasma) RIE apparatus, a CVD (Chemical Vapor Deposition) apparatus, and the like are employed.

Connection portion 13 connects forming portion 11 and removal portion 12 to each other so as to be able to carry an SiC substrate 1 therein. A region in connection portion 13 for carrying SiC substrate 1 (an internal space) can be cut off from the air.

Here, being cut off from the air (an atmosphere cut off from the air) refers to an atmosphere in which the air is not introduced, and refers, for example, to an atmosphere in which vacuum is produced or which contains an inert gas or a nitrogen gas. Specifically, an atmosphere cut off from the air refers, for example, to an atmosphere in which vacuum is produced or which is filled with nitrogen (N), helium (He), neon (Ne), argon (Ar), krypton (Kr), xenon (Xe), radon (Rn), or a gas which is combination thereof.

In the present embodiment, connection portion 13 couples the inside of forming portion 11 and the inside of removal portion 12 to each other. Connection portion 13 has a space for carrying an SiC semiconductor loaded out of forming portion 11 to removal portion 12 in the inside. Namely, connection portion 13 is provided in order to carry an SiC semiconductor from forming portion 11 to removal portion 12 without exposing the SiC semiconductor to the air.

Connection portion 13 has such a size that SiC substrate 1 can be carried therein. Alternatively, connection portion 13 may also have such a size that SiC substrate 1 as placed on a susceptor can be carried therein. Connection portion 13 is implemented, for example, by a load lock chamber coupling an exit of forming portion 11 and an entrance of removal portion 12 to each other.

Cleaning apparatus 10 may further include a first carrier portion arranged in connection portion 13, for carrying an SiC semiconductor from forming portion 11 to removal portion 12. Cleaning apparatus 10 may further include a second carrier portion for taking the SiC semiconductor, from which the oxide film has been removed in removal portion 12, out of cleaning apparatus 10, or for carrying the same to an oxide film forming portion for forming an oxide film forming a semiconductor device, in an atmosphere cut off from the air. The first carrier portion and the second carrier portion may be identical to or different from each other.

In addition, cleaning apparatus 10 may further include a cut-off portion arranged between forming portion 11 and connection portion 13, for cutting off the inside of forming portion 11 and the inside of connection portion 13 from each other. Moreover, cleaning apparatus 10 may further include a cut-off portion arranged between removal portion 12 and connection portion 13, for cutting off the inside of removal portion 12 and the inside of connection portion 13 from each other. The cut-off portion can include, for example, a valve, a door or the like capable of closing each communicating portion.

Cleaning apparatus 10 may further include a vacuum pump for exhausting an atmospheric gas in the inside or a replacement gas canister for replacing an atmospheric gas in the inside. The vacuum pump or the replacement gas canister may be connected to each of forming portion 11, removal portion 12 and connection portion 13, or to at least any one of them.

Though cleaning apparatus 10 may include various elements other than the above, for the sake of convenience of description, illustration and description of these elements will not be provided.

Though FIG. 1 shows a form in which connection portion 13 couples only forming portion 11 and removal portion 12 to each other, connection portion 13 is not particularly limited as such. For example, a chamber cut off from the air may be employed as connection portion 13 and forming portion 11 and removal portion 12 may be arranged in this chamber.

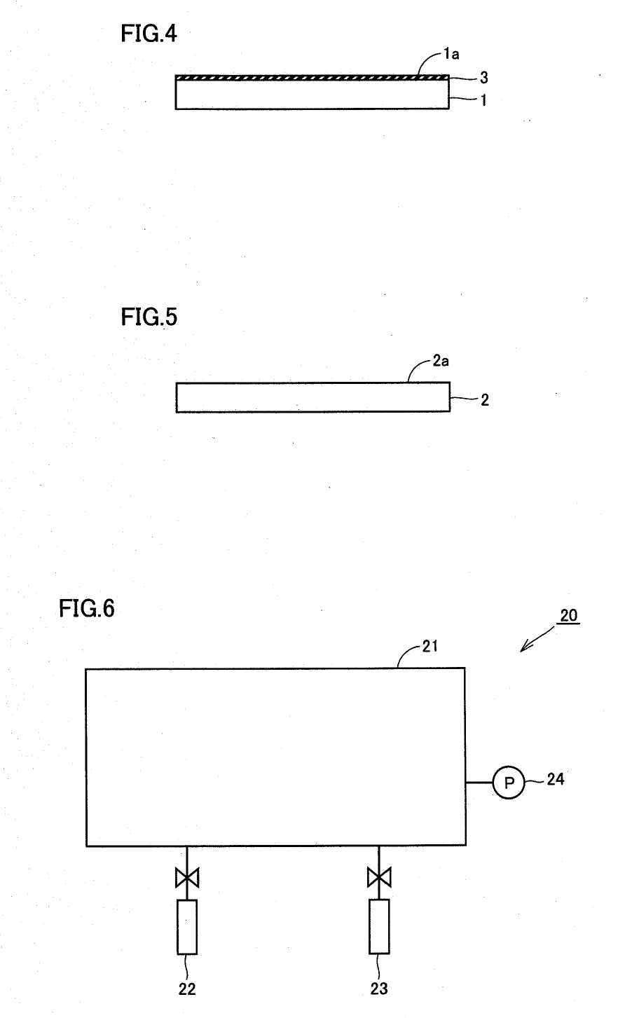

FIG. 2 is a cross-sectional view schematically showing an SiC semiconductor prepared in the first embodiment of the present invention. FIG. 3 is a flowchart showing a method of cleaning an SiC semiconductor in the first embodiment of the present invention. FIG. 4 is a cross-sectional view schematically showing a state in which an oxide film is formed on the SiC semiconductor in the first embodiment of the present invention. FIG. 5 is a cross-sectional view schematically showing a state in which the oxide film has been removed in the first embodiment of the present invention. In succession, a method of cleaning an SiC semiconductor in one embodiment of the present invention will be described with reference to FIGS. 1 to 5. In the present embodiment, a method of cleaning SiC substrate 1 shown in FIG. 2 as an SiC semiconductor will be described. In the present embodiment, SiC semiconductor cleaning apparatus 10 shown in FIG. 1 is employed.

As shown in FIGS. 2 and 3, initially, SiC substrate 1 having a surface 1a is prepared (step S1). Though SiC substrate 1 is not particularly limited, for example, it can be prepared with the following method.

Specifically, an SiC ingot grown, for example, with a vapor phase epitaxy method such as an HVPE (Hydride Vapor Phase Epitaxy) method, an MBE (Molecular Beam Epitaxy) method, an OMVPE (OrganoMetallic Vapor Phase Epitaxy) method, a sublimation method, and a CVD method, and a liquid phase epitaxy method such as a flux method and a high nitrogen pressure solution method, is prepared. Thereafter, an SiC substrate having a surface is cut from the SiC ingot. A cutting method is not particularly limited and the SiC substrate is cut from the SiC ingot by slicing or the like. Then, the surface of the cut SiC substrate is polished. The surface to be polished may be only a front surface, or a back surface opposite to the front surface may further be polished. A polishing method is not particularly limited, however, for example, CMP (Chemical Mechanical Polishing) is adopted in order to planarize the surface and to lessen such damages as flaws. In CMP, colloidal silica is employed as an abrasive, diamond or chromium oxide is employed as abrasive grains, and an adhesive, a wax or the like is employed as an fixing agent. In addition to or instead of CMP, other polishing such as an electric field polishing method, a chemical polishing method, a mechanical polishing method, and the like may further be performed. Alternatively, polishing may not be performed. Thus, SiC substrate 1 having surface 1a shown in FIG. 2 can be prepared. For example, a substrate having an n conductivity type and resistance of 0.02 Ωcm is employed as such SiC substrate 1.

Then, as shown in FIGS. 3 and 4, an oxide film 3 is formed on surface 1a of SiC substrate 1 (step S2). In step S2 in the present embodiment, oxide film 3 is formed in forming portion 11 of cleaning apparatus 10 shown in FIG. 1.

A method of forming oxide film 3 is not particularly limited, and for example, a method of oxidizing surface 1a of SiC substrate 1 by using a solution containing O, O plasma, thermal oxidation in an atmosphere containing an O gas, or the like is available.

An example of a solution containing O includes ozone water. Taking into account the fact that SiC is a stable compound, for example, ozone water having concentration, for example, not lower than 30 ppm is preferably employed. In this case, since decomposition of ozone can be suppressed and a speed of reaction between surface 1a and ozone can be increased, oxide film 3 can readily be formed on surface 1a.

Thermal oxidation containing an O gas is preferably carried out in a dry atmosphere, for example, at a temperature not lower than 700° C., in consideration of the fact that SiC is a stable compound. It is noted that the dry atmosphere refers to formation of oxide film 3 in vapor phase and it may contain an unintended liquid phase component.

Further, O plasma refers to plasma generated from a gas containing O element and it can be generated, for example, by supplying the O gas to the plasma generation apparatus. “Forming oxide film 3 with O plasma” means that oxide film 3 is formed with plasma using a gas containing O element. In other words, it means formation of oxide film 3 by treatment with plasma generated from a gas containing O element.

In a case where O plasma is employed in step S2, oxide film 3 is preferably formed at a temperature not lower than 200° C. and not higher than 700° C. In this case, oxide film 3 can be formed with improved throughput. In addition, since electric power can be reduced, oxide film 3 can be formed with lower cost. Moreover, the oxide film can uniformly be formed.

In a case where O plasma is employed in step S2, the oxide film is formed in an atmosphere not lower than 0.1 Pa and not higher than 20 Pa. In this case, reactivity to surface 1a of SiC substrate 1 can be enhanced.

In step S2, oxide film 3 having a thickness, for example, not smaller than 1 molecular layer and not greater than 30 nm is formed. By forming oxide film 3 having a thickness not smaller than 1 molecular layer, an impurity, particles and the like on surface 1a can be taken into the oxide film. By forming an oxide film not thicker than 30 nm, oxide film 3 is readily removed in step S3 which will be described later.

As this step S2 is performed, particles, a metal impurity and the like deposited on surface 1a of SiC substrate 1 are taken into the surface or into the inside of oxide film 3. It is noted that oxide film 3 is composed, for example, of silicon oxide.

Referring next to FIG. 1, SiC substrate 1 having oxide film 3 formed in forming portion 11 is carried to removal portion 12. Here, SiC substrate 1 is carried within connection portion 13 set to an atmosphere cut off from the air. In other words, SiC substrate 1 is arranged in an atmosphere cut off from the air, between step S2 of forming oxide film 3 and step S3 of removing oxide film 3. Thus, deposition of an impurity contained in the air onto SiC substrate 1 after oxide film 3 is formed can be suppressed.

Then, as shown in FIGS. 3 and 5, oxide film 3 is removed (step S3). In this step S3, oxide film 3 is removed with halogen plasma or H plasma. In step S3 in the present embodiment, oxide film 3 is removed in removal portion 12 of cleaning apparatus 10 shown in FIG. 1.

Here, halogen plasma refers to plasma generated from a gas containing halogen element. The halogen element refers to F, chlorine (Cl), bromine (Br), and iodine (I). “Removing oxide film 3 with halogen plasma” means that oxide film 3 is etched with plasma using a gas containing halogen element. In other words, it means that oxide film 3 is removed by treatment with plasma generated from a gas containing halogen element.

Use of F plasma as the halogen plasma is preferred. Here, F plasma refers to plasma generated from gas containing F element, and it can be generated, for example, by supplying to the plasma generation apparatus, a gas of carbon tetrafluoride (CF4), methane trifluoride (CHF₃), chlorofluorocarbons (C₂F₆), sulfur hexafluoride (SF₆), nitrogen trifluoride (NF₃), xenon difluoride (XeF₂), fluorine (F₂), and chlorine fluoride (ClF₃) alone, or a gas mixture thereof. “Removing oxide film 3 with F plasma” means etching of oxide film 3 with plasma using a gas containing F element. In other words, it means removal of oxide film 3 by treatment with plasma generated from a gas containing F element.

H plasma refers to plasma generated from a gas containing H element, and it can be generated, for example, by supplying an H₂ gas to the plasma generation apparatus. “Removing oxide film 3 with H plasma” means etching of oxide film 3 with plasma using a gas containing H element. In other words, it means removal of oxide film 3 by treatment with plasma generated from a gas containing H element.

In this step S3, oxide film 3 is removed preferably at a temperature not lower than 20° C. and not higher than 400° C.

In addition, in this step S3, oxide film 3 is removed preferably at a pressure not lower than 0.1 Pa and not higher than 20 Pa.

By performing this step S3, the oxide film that has taken in an impurity, particles and the like in step S2 can be removed, and therefore the impurity, the particles and the like deposited on surface 1a of SiC substrate 1 prepared in step S1 can be removed.

By performing the steps (steps S1 to S3) above, for example as shown in FIG. 5, an SiC substrate 2 having a surface 2a having less impurity and particles can be realized.

It is noted that steps S2 and S3 above may be repeated. Moreover, after step S1, the step of cleaning with other agents, the step of rinsing with pure water, the drying step, and the like may additionally be performed as necessary. Examples of other agents include SPM containing sulfuric acid and a hydrogen peroxide solution. In a case of cleaning with SPM before step S2, an organic substance can also be removed. Further, RCA cleaning may be performed before step S2.

As described above, the method of cleaning SiC substrate 1 representing the SiC semiconductor in the present embodiment includes the steps of forming oxide film 3 on surface 1a of SiC substrate 1 (step S2) and removing oxide film 3 (step S3), and oxide film 3 is removed with halogen plasma or H plasma in the removing step (step S3).

By forming oxide film 3 on surface 1a of SiC substrate 1 in step S2, oxide film 3 can be formed with a metal impurity such as titanium (Ti), particles and the like that have deposited on surface 1a being taken therein. Since oxide film 3 is removed by making use of active halogen in halogen plasma or active H in H plasma, influence by anisotropy due to plane orientation of SiC can be lessened. Therefore, oxide film 3 formed on surface 1a of SiC substrate 1 can be removed to thereby lessen in-plane variation. Namely, oxide film 3 can uniformly be removed without being affected by film quality of oxide film 3. Therefore, an impurity, particles and the like on surface 1a of SiC substrate 1 can be removed to lessen in-plane variation. In addition, oxide film 3 formed on surface 1a of SiC substrate 1 can be prevented also from locally remaining. Furthermore, since development of etching of only a partial region in the plane of SiC substrate 1 can be suppressed, local recess in surface 1a of SiC substrate 1 can also be suppressed.

The present inventor paid attention to the fact that an SiC substrate is chemically stable and found that, even though a method of removing oxide film 3 with the use of halogen plasma or H plasma causing damage in an Si substrate is applied to an SiC substrate, SiC substrate 1 is less likely to be damaged. Therefore, even though halogen plasma or H plasma is used in step S3, damage to SiC substrate 1 is less.

Therefore, according to the method of cleaning SiC substrate 1 in the present embodiment, an impurity, particles and the like can be removed to thereby lessen in-plane variation of surface 1a and damage caused by cleaning is less. Thus, SiC substrate 1 can be cleaned such that good surface characteristics are achieved.

In addition, oxide film 3 is removed with halogen plasma or H plasma in a dry atmosphere in step S3. Since plasma is clean, it is environmentally friendly. Further, since the plasma etching step does not require such post-treatment as washing with water and drying as compared with cleaning in a wet atmosphere (an atmosphere containing a liquid phase), SiC substrate 1 can be cleaned in a simplified manner. Furthermore, since post-treatment such as washing with water is not necessary, generation of a mark by water on surface 2a of SiC substrate 2 after step S3 can be suppressed.

In the method of cleaning SiC substrate 1 representing the SiC semiconductor in the present embodiment above, preferably, in the step of forming oxide film 3 (step S2), O plasma is employed.

The present inventor paid attention to the fact that, since SiC is a compound more thermally stable than Si, a surface of an SiC semiconductor is less likely to be oxidized when the cleaning method in Patent Literature 1 above is applied to the SiC semiconductor. Namely, though the cleaning method in Patent Literature 1 above can oxidize the surface of Si, it cannot sufficiently oxidize the surface of SiC and hence cannot sufficiently clean the surface of the SiC semiconductor. Then, as a result of the present inventor's dedicated studies for oxidizing the surface of the SiC semiconductor, the present inventor found that oxide film 3 can readily be formed by making use of active O by using O plasma. In addition, crystal of SiC is strong and hence damage to SiC substrate 1 is less even with the use of O plasma. Therefore, SiC substrate 1 can be cleaned such that better surface characteristics are achieved.

In addition, oxide film 3 is formed on surface 1a of SiC substrate 1 with O plasma (step S2) and oxide film 3 is removed with halogen plasma or H plasma (step S3), so that surface 1a of SiC substrate 1 can be cleaned in a dry atmosphere (in a vapor phase). In the case of cleaning in a wet atmosphere (an atmosphere containing a liquid phase), metal ions may be included in a liquid phase, instruments and the like used for cleaning. Further, increase in particles originating from a cleaning chamber is likely. Therefore, cleaning in a dry atmosphere can decrease a metal impurity and particles at the surface more than in a wet atmosphere (an atmosphere containing a liquid phase).

Apparatus 10 for cleaning SiC substrate 1 representing the SiC semiconductor in the embodiment of the present invention includes forming portion 11 for forming oxide film 3 on surface 1a of SiC substrate 1, removal portion 12 for removing oxide film 3 with the use of halogen plasma or H plasma, and connection portion 13 connecting forming portion 11 and removal portion 12 to each other so as to allow an SiC substrate to be carried therein, of which region for carrying SiC substrate 1 can be cut off from the air.

According to apparatus 10 for cleaning SiC substrate 1 in the present embodiment, SiC substrate 1 can be prevented from being exposed to the air after oxide film 3 is formed on SiC substrate 1 in forming portion 11 and while oxide film 3 is removed in removal portion 12. Thus, an impurity in the air can be prevented from redepositing onto surface 1a of SiC substrate 1. Further, since oxide film 3 that has taken in an impurity, particles and the like is removed with halogen plasma or H plasma, influence by anisotropy due to plane orientation of SiC can be lessened. Thus, oxide film 3 formed on surface 1a of SiC substrate 1 can be removed to thereby lessen in-plane variation. Therefore, SiC substrate 1 can be cleaned such that good surface characteristics are achieved.

(Variation)

FIG. 6 is a schematic diagram of an apparatus for cleaning an SiC semiconductor in a variation of the first embodiment of the present invention. The apparatus for cleaning an SiC semiconductor in the variation of the present embodiment will be described with reference to FIG. 6.

As shown in FIG. 6, a cleaning apparatus 20 in the variation includes a chamber 21, a first gas supply portion 22, a second gas supply portion 23, and a vacuum pump 24. First gas supply portion 22, second gas supply portion 23 and vacuum pump 24 are connected to chamber 21.

Chamber 21 is a plasma generation apparatus accommodating SiC substrate 1 therein. A parallel plate RIE apparatus, an ICP RIE apparatus, an ECR RIE apparatus, an SWP RIE apparatus, a CVD apparatus, and the like are employed as the plasma generation apparatus.

First and second gas supply portions 22 and 23 each supply a gas, which is a plasma generation source, to chamber 21. First gas supply portion 22 supplies a gas containing, for example, O. Therefore, first gas supply portion 22 can generate O plasma in chamber 21 so that oxide film 3 can be formed on surface 1a of SiC substrate 1. Second gas supply portion 23 supplies a gas containing, for example, halogen or H. Therefore, second gas supply portion 23 can generate halogen plasma or H plasma in chamber 21 so that oxide film 3 formed on surface 1a of SiC substrate 1 can be removed.

Vacuum pump 24 produces vacuum in chamber 21. Therefore, after oxide film 3 is formed on surface 1a of SiC substrate 1 with the use of O plasma, vacuum is produced in chamber 21 and then oxide film 3 can be removed with halogen plasma or H plasma. It is noted that it is not necessary to provide vacuum pump 24.

It is noted that the cleaning apparatus shown in FIG. 6 may include various elements other than the above, however, for the sake of convenience of description, these elements are not illustrated and described.

From the foregoing, SiC semiconductor cleaning apparatus 20 in the variation of the present embodiment includes a forming portion for forming oxide film 3 on surface 1a of SiC substrate 1 representing the SiC semiconductor and a removal portion for removing oxide film 3 with halogen plasma or H plasma, and the forming portion and the removal portion are common (chamber 21).

According to SiC semiconductor cleaning apparatus 20 in the variation, since it is not necessary to carry SiC substrate 1 after oxide film 3 is formed on SiC substrate 1 in the forming portion and while oxide film 3 is removed in the removal portion, SiC substrate 1 is not exposed to the air. In other words, the SiC substrate is arranged in an atmosphere cut off from the air between step S2 of forming oxide film 3 and step S3 of removing oxide film 3. Thus, an impurity in the air can be prevented from redepositing onto surface 1a of SiC substrate 1 during cleaning of SiC substrate 1. In addition, since oxide film 3 that has taken in an impurity, particles and the like is removed with halogen plasma or H plasma, influence by anisotropy due to plane orientation of SiC can be lessened. Thus, oxide film 3 formed on surface 1a of SiC substrate 1 can be removed to thereby lessen in-plane variation. Therefore, SiC substrate 1 can be cleaned such that good surface characteristics are achieved.

### Second Embodiment

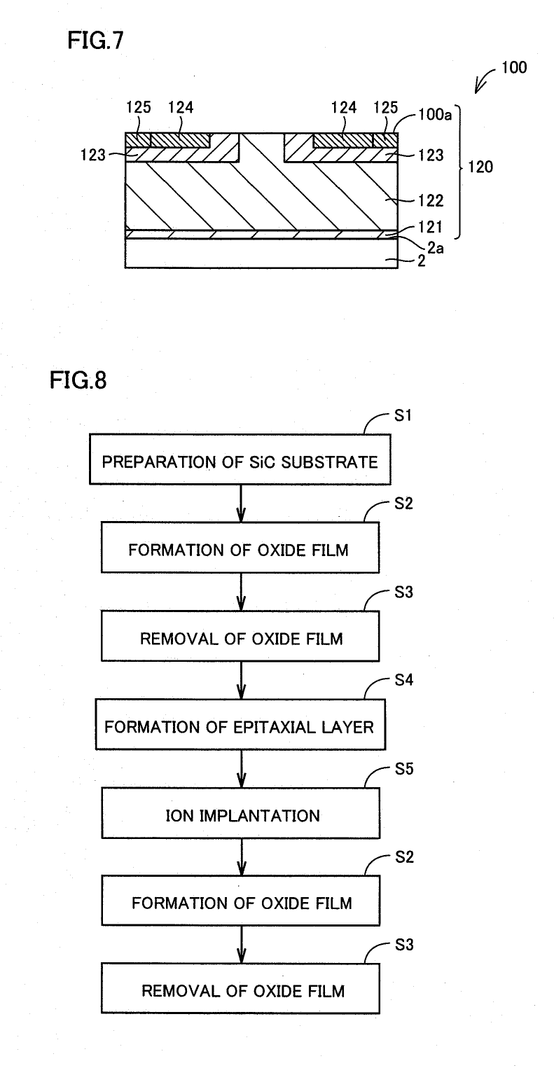

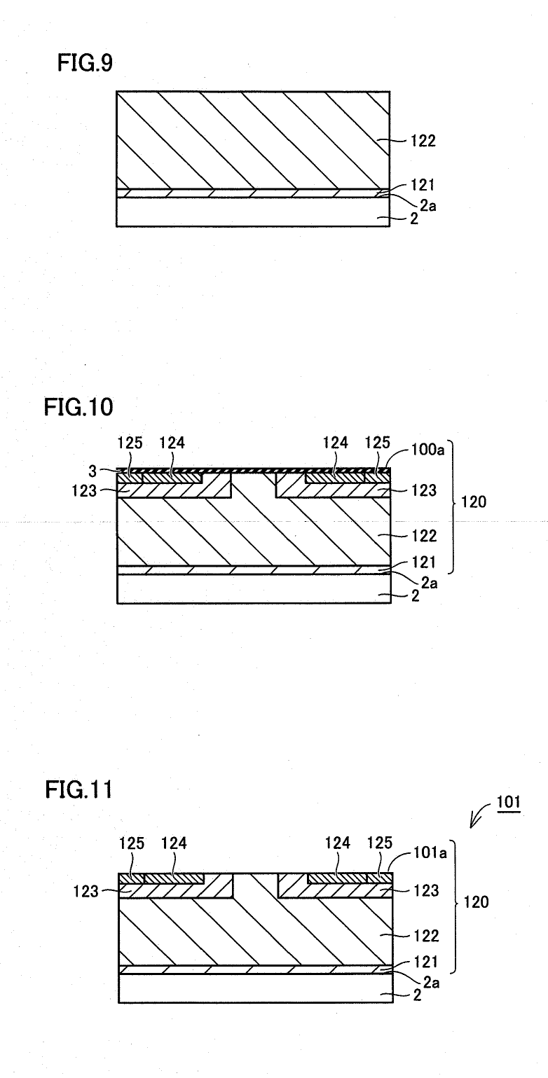

FIG. 7 is a cross-sectional view schematically showing an SiC semiconductor to be cleaned in a second embodiment of the present invention. FIG. 8 is a flowchart showing a method of cleaning an SiC semiconductor in the second embodiment of the present invention. FIGS. 9 to 11 are cross-sectional views each schematically showing one step in the method of cleaning an SiC semiconductor in the second embodiment of the present invention. A method of cleaning an SiC semiconductor in the present embodiment will be described with reference to FIGS. 2, 4, 5, and 7 to 11. In the present embodiment, a method of cleaning an epitaxial wafer 100 as an SiC semiconductor, including SiC substrate 2 and an epitaxial layer 120 formed on SiC substrate 2 as shown in FIG. 7, will be described.

Initially, as shown in FIGS. 2 and 8, SiC substrate 1 is prepared (step S1). Since step S1 is the same as in the first embodiment, description thereof will not be repeated.

Then, as shown in FIGS. 4 and 8, oxide film 3 is formed on surface 1a of SiC substrate 1 (step S2) and thereafter oxide film 3 is removed as shown in FIGS. 5 and 8 (step S3). Since steps S2 and S3 are the same as in the first embodiment, description thereof will not be repeated. Thus, surface 1a of SiC substrate 1 can be cleaned and SiC substrate 2 having surface 2a having less impurity and particles can be prepared. It is noted that it is not necessary to clean surface 1a of SiC substrate 1.

Then, as shown in FIGS. 7 to 9, epitaxial layer 120 is formed on surface 2a of SiC substrate 2 with a vapor phase epitaxy method, a liquid phase epitaxy method, or the like (step S4). In the present embodiment, for example, epitaxial layer 120 is formed as follows.

Specifically, as shown in FIG. 9, a buffer layer 121 is formed on surface 2a of SiC substrate 2. Buffer layer 121 is an epitaxial layer composed, for example, of SiC having an n conductivity type and a thickness, for example, of 0.5 μm. In addition, concentration of a conductive impurity in buffer layer 121 is, for example, 5×10¹⁷ cm⁻³.

Thereafter, as shown in FIG. 9, a breakdown voltage holding layer 122 is formed on buffer layer 121. As breakdown voltage holding layer 122, a layer composed of SiC having an n conductivity type is formed with a vapor phase epitaxy method, a liquid phase epitaxy method or the like. Breakdown voltage holding layer 122 has a thickness, for example, of 15 μm. In addition, concentration of an n-type conductive impurity in breakdown voltage holding layer 122 is, for example, 5×10¹⁵ cm⁻³.

Then, as shown in FIGS. 7 and 8, ions are implanted into epitaxial layer 120 (step S5). In the present embodiment, as shown in FIG. 7, a p-type well region 123, an n⁺ source region 124, and a p⁺ contact region 125 are formed as follows. Initially, well region 123 is formed by selectively implanting an impurity having a p conductivity type into a part of breakdown voltage holding layer 122. Thereafter, source region 124 is formed by selectively implanting an n-type conductive impurity into a prescribed region, and contact region 125 is formed by selectively implanting a conductive impurity having a p conductivity type into a prescribed region. It is noted that selective implantation of an impurity is carried out, for example, by using a mask formed from an oxide film. This mask is removed after an impurity is implanted.

After such an implantation step, an activation annealing treatment may be performed. For example, in an argon atmosphere, annealing for 30 minutes at a heating temperature of 1700° C. is carried out.

Through these steps, as shown in FIG. 7, epitaxial wafer 100 including SiC substrate 2 and epitaxial layer 120 formed on SiC substrate 2 can be prepared.

Then, a surface 100a of epitaxial wafer 100 is cleaned. Specifically, as shown in FIGS. 8 and 10, oxide film 3 is formed on surface 100a of epitaxial wafer 100 (step S2).

This step S2 is the same as step S2 of forming oxide film 3 on surface 1a of SiC substrate 1 in the first embodiment. It is noted that, if surface 100a is damaged by ion implantation into the epitaxial wafer in step S5, a damaged layer may be oxidized in order to remove this damaged layer. In this case, a thickness exceeding 10 nm and not greater than 100 nm is oxidized from surface 100a toward SiC substrate 2, for example, with O plasma or thermal oxidation not lower than 1100° C.

Then, oxide film 3 formed on surface 100a of epitaxial wafer 100 is removed with halogen plasma or H plasma (step S3). Since this step S3 is the same as step S3 of removing oxide film 3 formed on surface 1a of SiC substrate 1 in the first embodiment, description thereof will not be repeated.

By performing the steps (S1 to S5) above, an impurity, particles and the like deposited onto surface 100a of epitaxial wafer 100 can be cleaned. It is noted that step S2 and step S3 can repeatedly be performed and other cleaning steps may further be included as in the first embodiment. Thus, for example as shown in FIG. 11, an epitaxial wafer 101 having a surface 101a having less impurity and particles can be realized.

It is noted that, in cleaning an epitaxial wafer in the present embodiment, any of cleaning apparatus 10 shown in FIG. 1 and cleaning apparatus 20 shown FIG. 6 may be employed. In the case of using cleaning apparatus 10 shown in FIG. 1, epitaxial wafer 100 having oxide film 3 formed thereon is carried through connection portion 13 of cleaning apparatus 10. Therefore, connection portion 13 has such a shape as being able to carry epitaxial wafer 100 or a susceptor on which epitaxial wafer 100 is placed.

As described above, according to the method of cleaning epitaxial wafer 100 in the present embodiment, oxide film 3 is removed with halogen plasma or H plasma that cannot be adopted for Si due to damage, because crystal of SiC is strong. Since halogen plasma and H plasma are clean and high in uniformity, oxide film 3 can be removed with influence by anisotropy due to plane orientation being lessened. Therefore, cleaning can be performed such that better characteristics of surface 100a of epitaxial wafer 100 are achieved.

By performing the method of cleaning epitaxial wafer 100 representing the SiC semiconductor in the present embodiment, as shown in FIG. 11, epitaxial wafer 101 having surface 101a having less impurity, particles and the like can be manufactured. By forming an insulating film constituting a semiconductor device such as a gate oxide film on this surface 101a, characteristics of the insulating film can be improved and an impurity, particles and the like present at an interface between surface 101a and the insulating film and in the insulating film can be decreased. Therefore, a breakdown voltage at the time when a reverse voltage is applied to a semiconductor device can be improved and stability and long-term reliability of an operation at the time when a forward voltage is applied can be improved. Therefore, the method of cleaning an SiC semiconductor in the present invention is particularly suitably used for surface 100a of epitaxial wafer 100 before a gate oxide film is formed.

Since epitaxial wafer 101 cleaned with the cleaning method according to the present embodiment can achieve improved characteristics of an insulating film as a result of formation of the insulating film on cleaned surface 101a, it can suitably be used for a semiconductor device having an insulating film. Therefore, epitaxial wafer 101 cleaned according to the present embodiment can suitably be employed, for example, for a semiconductor device having an insulating gate electric field effect portion such as a MOSFET (Metal Oxide Semiconductor Field Effect Transistor) or an IGBT (Insulated Gate Bipolar Transistor), a JFET (Junction Field-Effect Transistor), and the like.

Here, in the first embodiment, a method of cleaning surface 1a of SiC substrate 1 has been described. In the second embodiment, a method of cleaning surface 100a of epitaxial wafer 100 including SiC substrate 2 and SiC epitaxial layer 120 formed on SiC substrate 2, with SiC epitaxial layer 120 having ion-implanted surface 100a, has been described. The cleaning method according to the present invention, however, is also applicable to an SiC epitaxial layer having a surface in which ions are not implanted. In addition, in cleaning epitaxial wafer 100, at least one of surface 2a of SiC substrate 2 forming epitaxial wafer 100 and surface 100a of epitaxial wafer 100 may be cleaned. Namely, the method of cleaning an SiC semiconductor according to the present invention includes (i) a case of cleaning an SiC substrate and (ii) a case of cleaning an epitaxial wafer having an SiC substrate and an SiC epitaxial layer formed on the SiC substrate, and the SiC epitaxial layer in (ii) includes a layer into which ions have been implanted through a front surface and a layer into which ion are not implanted.

### EXAMPLES

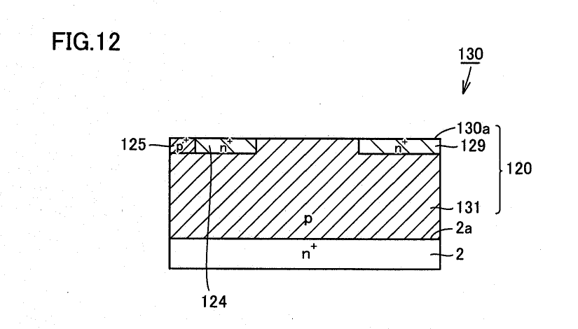

In the present example, an effect of cleaning an epitaxial wafer 130 shown in FIG. 12 and representing an SiC semiconductor and removing an oxide film with the use of halogen plasma was examined. FIG. 12 is a cross-sectional view schematically showing epitaxial wafer 130 cleaned in the example.

### Present Inventive Example 1

Initially, a 4H—SiC substrate having surface 2a was prepared as SiC substrate 2 (step S1).

Then, as a layer forming epitaxial layer 120, a p-type SiC layer 131 having a thickness of 10 μm and impurity concentration of 1×10¹⁶ cm⁻³ was grown with the CVD method (step S4).

Then, using SiO₂ as a mask, source region 124 and a drain region 129 each having impurity concentration of 1×10¹⁹ cm⁻³ were formed, with phosphorus (P) being used as an n-type impurity. In addition, contact region 125 having impurity concentration of 1×10¹⁹ cm⁻³ was formed, with aluminum (Al) being used as a p-type impurity (step S5). It is noted that the mask was removed after each ion was implanted.

Then, activation annealing treatment was performed. In this activation annealing treatment, an Ar gas was employed as an atmospheric gas, and such conditions as a heating temperature from 1700 to 1800° C. and a heating time period of 30 minutes were set.

Thus, epitaxial wafer 130 having a surface 130a was prepared. In succession, cleaning apparatus 20 shown in FIG. 6 was used to clean surface 130a of epitaxial wafer 130.

An oxide film was formed with O plasma (step S2). In this step S2, parallel plate RIE cleaning apparatus 20 shown in FIG. 6 was used, epitaxial wafer 130 was arranged in chamber 21, and O plasma treatment was performed under the following conditions. The oxide film was formed in such a manner that an O² gas was supplied from first gas supply portion 22 at 50 sccm, a pressure of an atmosphere in chamber 21 was set to 1.0 Pa, a heating temperature of a back surface of SiC substrate 2 of epitaxial wafer 130 was set to 400° C., and electric power (power) of 500 W was applied. Thus, it was confirmed that an oxide film of a thickness of 1 nm could be formed on surface 130a of epitaxial wafer 130.

Then, the oxide film was removed with F plasma while epitaxial wafer 130 was arranged in chamber 21 (step S3). In this step S3, the oxide film was removed in such a manner that supply of O from first gas supply portion 22 was stopped, an F₂ gas was supplied from second gas supply portion 23 at 30 sccm, a pressure of an atmosphere in chamber 21 was set to 1.0 Pa, a heating temperature of the back surface of SiC substrate 2 of epitaxial wafer 130 was set to 400° C., and electric power (power) of 300 W was applied. Thus, it was confirmed that the oxide film formed in step S2 could uniformly be removed (with in-plane variation being lessened).

Through the steps (steps S1 to S5) above, surface 130a of epitaxial wafer 130 was cleaned. The surface of epitaxial wafer 130 after cleaning in Present Inventive Example 1 had less impurity and particles than surface 130a before cleaning. In addition, the oxide film did not locally remain on the surface of epitaxial wafer 130 after cleaning in Present Inventive Example 1

### Comparative Example 1

In Comparative Example 1, initially, epitaxial wafer 130 shown in FIG. 12 as in Present Inventive Example 1 was prepared.

Then, epitaxial wafer 130 was cleaned. Though the method of cleaning epitaxial wafer 130 in Comparative Example 1 was basically the same as the method of cleaning epitaxial wafer 130 in Present Inventive Example 1, it was different in that HF was employed instead of F plasma in step S3 of removing the oxide film and cleaning apparatus 10 shown in FIG. 1 was employed instead of cleaning apparatus 20 shown in FIG. 6.

Specifically, in Comparative Example 1, the oxide film was formed on surface 130a of prepared epitaxial wafer 130 with O plasma in cleaning apparatus 10 shown in FIG. 1 (step S2). In this step S2, parallel plate RIE was employed as forming portion 11, epitaxial wafer 130 was arranged in forming portion 11, and O plasma was performed under the following conditions as in Present Inventive Example 1. The oxide film was formed in such a manner that an O₂ gas was supplied at 50 sccm, a pressure of an atmosphere in forming portion 11 was set to 1.0 Pa, a heating temperature of the back surface of SiC substrate 2 of epitaxial wafer 130 was set to 400° C., and electric power (power) of 500 W was applied. Thus, it was confirmed that the oxide film having a thickness of 1 nm could be formed on surface 130a of epitaxial wafer 130.

Then, epitaxial wafer 130 having the oxide film formed in forming portion 11 was carried to removal portion 12. Here, epitaxial wafer 130 was carried through connection portion 13 set to an atmosphere cut off from the air.

Then, the oxide film was removed with HF. In this step, oxide film 3 was removed by causing HF to stay in removal portion 12 and immersing epitaxial wafer 130 in HF.

Thereafter, epitaxial wafer 130 was taken out of cleaning apparatus 10 and the surface of epitaxial wafer 130 was cleaned with pure water (the pure water rinsing step). Then, epitaxial wafer 130 was dried with a spinning method (the drying step).

Then, the step of forming an oxide film with the use of O plasma described above (step S2), the step of removing the oxide film with HF, the pure water rinsing step, and the drying step were repeated.

Through the steps above, surface 130a of epitaxial wafer 130 was cleaned. In Comparative Example 1, the oxide film formed in step S2 could not be removed as uniformly as in Present Inventive Example 1 (with less in-plane variation), probably for the following reasons. In Comparative Example 1, the oxide film was removed with HF, and in-plane variation in removal of the oxide film was caused by difference in etching rate in a plane of epitaxial wafer 130 due to film quality of the oxide film depending on plane orientation.

From the foregoing, it was found that, according to the present example, by forming an oxide film on a surface of an SiC semiconductor and removing this oxide film with the use of halogen plasma, an impurity, particles and the like deposited onto the surface can be removed to lessen in-plane variation, and hence cleaning with good surface characteristics of the SiC semiconductor can be performed.

Though the embodiments and the example of the present invention have been described above, combination of features in each embodiment and example as appropriate is also originally intended. In addition, it should be understood that the embodiments and the example disclosed herein are illustrative and non-restrictive in every respect. The scope of the present invention is defined by the terms of the claims, rather than the embodiments and the example above, and is intended to include any modifications within the scope and meaning equivalent to the terms of the claims.

### REFERENCE SIGNS LIST

1, 2 SiC substrate; 1a, 2a, 100a, 101a, 130a surface; 3 oxide film; 10, 20 cleaning apparatus; 11 forming portion; 12 removal portion; 13 connection portion; 21 chamber; 22 first gas supply portion; 23 second gas supply portion; 24 vacuum pump; 100, 101, 130 epitaxial wafer; 120 epitaxial layer; 121 buffer layer; 122 breakdown voltage holding layer; 123 well region; 124 source region; 125 contact region; 129 drain region; and 131 p-type SiC layer.

1. A method of cleaning a silicon carbide semiconductor, comprising the steps of:
forming an oxide film on a surface of a silicon carbide semiconductor; and
removing said oxide film,
in said step of removing said oxide film, halogen plasma or hydrogen plasma being used.

2. The method of cleaning a silicon carbide semiconductor according to claim 1, wherein
in said step of removing said oxide film, fluorine plasma is used as said halogen plasma.

3. The method of cleaning a silicon carbide semiconductor according to claim 1, wherein
in said step of removing said oxide film, said oxide film is removed at a temperature not lower than 20° C. and not higher than 400° C.

4. The method of cleaning a silicon carbide semiconductor according to claim 1, wherein
in said step of removing said oxide film, said oxide film is removed at a pressure not lower than 0.1 Pa and not higher than 20 Pa.

5. The method of cleaning a silicon carbide semiconductor according to claim 1, wherein
in said step of forming an oxide film, oxygen plasma is used.

6. The method of cleaning a silicon carbide semiconductor according to claim 1, wherein
between said step of forming an oxide film and said step of removing said oxide film, said silicon carbide semiconductor is arranged in an atmosphere cut off from air.

7. An apparatus for cleaning a silicon carbide semiconductor, comprising:
a forming portion for forming an oxide film on a surface of a silicon carbide semiconductor;
a removal portion for removing said oxide film with halogen plasma or hydrogen plasma; and
a connection portion for connecting said forming portion and said removal portion to each other for allowing said silicon carbide semiconductor to be carried therein, wherein
a region in said connection portion for carrying said silicon carbide semiconductor can be cut off from air.

8. An apparatus for cleaning a silicon carbide semiconductor, comprising:
a forming portion for forming an oxide film on a surface of a silicon carbide semiconductor; and
a removal portion for removing said oxide film with halogen plasma or hydrogen plasma,
said forming portion and said removal portion being common.
